(19) United States
(12) Patent Application Publication
(10) Pub. No.: US 2025/0354881 A1
(43) Pub. Date: Nov. 20, 2025

(54) APPARATUS AND METHODS FOR TACTILE SENSING

(71) Applicant: The Trustees of Columbia University in the City of New York, New York, NY (US)

(72) Inventors: Matei CIOCARLIE, New York, NY (US); Ioannis KYMISSIS, New York, NY (US); Eric Thomas CHANG, New York, NY (US); Peter Jaron BALLENTINE, New York, NY (US)

(21) Appl. No.: 19/210,531

(22) Filed: May 16, 2025

Related U.S. Application Data
(60) Provisional application No. 63/648,533, filed on May 16, 2024.

(51) Int. Cl. G01L 5/22; G01L 5/165; G03F 7/00; G03F 7/16

(52) U.S. Cl. CPC G01L 5/228; G01L 5/165; G03F 7/0035; G03F 7/167

(57) ABSTRACT

Apparatus and methods are disclosed for tactile sensing techniques including a first sensing device; a structure configured to support the first sensing device; and an electronic device configured to process a first signal generated by the first sensing device, wherein the first sensing device is configured to generate the first signal in response to a first physical effect. A second sensing device is configured to generate a second signal in response to a second physical effect, wherein the second signal is processed in combination with the first signal. The first physical effect can be a distributed mechanical effect with a first frequency and the second physical effect can be a static effect with a second frequency lower than the first frequency. The first sensing device can include a polyvinylidene fluoride (PVDF) film, which includes a plurality of tactile elements.

This application claims the benefit of priority to U.S. Provisional Application No. 63/648,533, entitled “Apparatus and Methods for Tactile Sensing,” filed on May 16, 2024, the disclosure of which is incorporated by reference herein in its entirety.

This patent disclosure contains material that is subject to copyright protection. The copyright owner has no objection to the facsimile reproduction by anyone of the patent document or the patent disclosure as it appears in the U.S. Patent and Trademark Office patent file or records, but otherwise reserves any and all copyright rights.

This invention was made with government support under 80NSSC22K1179 awarded by NASA and 2036197 awarded by the National Science Foundation. The government has certain rights in the invention.

### TECHNICAL FIELD

Embodiments of the disclosure relate generally to haptic technology. In some non-limiting implementations, the disclosure relates to tactile sensing.

### BACKGROUND

The human skin uses a complex network of tactile sensors or mechanoreceptors to detect physical parameters from the external environment, such as pressure, vibration, texture, temperature, hardness, shape, or size. Tactile sensing technology can replicate mechanisms of these sensors so that various physical parameters can be artificially captured and processed by systems employing robotics and/or other automated devices.

### SUMMARY

Apparatus and methods are disclosed for tactile sensing techniques. In one embodiment, a sensing apparatus is provided that comprises a first sensing device; a structure configured to support the first sensing device; and an electronic device configured to process a first signal generated by the first sensing device, wherein the first sensing device is configured to generate the first signal in response to a first distributed mechanical effect with a first frequency. The first distributed mechanical effect corresponds to a change of a mechanical force. In another embodiment, the sensing apparatus further comprises a second sensing device supported by the structure, the second sensing device configured to generate a second signal in response to a second physical effect, wherein the electronic device is configured to process the first signal and the second signal. The second sensing device can have a different response time and/or a different sensitivity level compared to the first sensing device.

In a further embodiment, a sensing method is provided that comprises generating, by a first sensing device, a first signal in response to a first distributed mechanical effect with a first frequency; generating, by a second sensing device, a second signal in response to a second physical effect; and processing, by an electronic device, the first signal in combination with the second signal.

The first distributed mechanical effect with a first frequency corresponds to a change of a mechanical force, in accordance with an embodiment. The second physical effect can be a static effect with a second frequency lower than the first frequency, in accordance with another embodiment. In yet another embodiment, the first sensing device includes a polyvinylidene fluoride (PVDF) film. The PVDF film can include a plurality of tactile elements in some examples. In a further embodiment, the second sensing device includes a capacitive transducer. The second sensing device can have a different response time and/or a different sensitivity level compared to the first sensing device.

In yet another embodiment, a method for manufacturing a tactile sensing device is provided that comprises preparing a base material; evaporating at least one layer of first deposit material onto a first side of the base material; and photolithographically creating a pattern on the first deposit material using a mask, wherein the pattern includes a plurality of electrodes used to send signals for tactile sensing. In a further embodiment, the method of for manufacturing a tactile sensing device further includes evaporating at least one layer of second deposit material onto a second side of the base material. In an embodiment, the base material is polyvinylidene fluoride (PVDF) film. In another embodiment, the method further includes depositing a first layer of a compliant material onto the base material, photolithographically creating a pattern on the first deposit material using a mask, wherein the first deposit material is on the first layer of the compliant material, and depositing a second layer of the compliant material onto the first deposit material.

The present disclosure will now be described in more detail with reference to particular embodiments thereof as shown in the accompanying drawings. While the present disclosure is described below with reference to particular embodiments, it should be understood that the present disclosure is not limited thereto. Those of ordinary skill in the art having access to the teachings herein will recognize additional implementations, modifications, and embodiments, as well as other fields of use, which are within the scope of the present disclosure as described herein.

### BRIEF DESCRIPTION OF THE DRAWINGS

Various objectives and features of the disclosed subject matter can be more fully appreciated with reference to the following detailed description of the enclosed subject matter when considered in connection with the following drawings. The following drawings should not be construed as limiting the present disclosure and are intended to be illustrative only.

FIG. 1 illustrates an example sensing apparatus, according to some embodiments.

FIGS. 2A-2B illustrate examples of a sensing device, according to some embodiments.

FIGS. 3A-3B illustrate examples of structures and electronic devices for sensing, according to some embodiments.

FIG. 4 illustrates an example electronic device for sensing, according to some embodiments.

FIGS. 5A-5B illustrate example structures for sensing, according to some embodiments.

FIG. 6 is a simplified diagram illustrating an example method for manufacturing a sensing device, according to some embodiments.

FIG. 7 illustrates an example sensing apparatus, according to some embodiments.

FIG. 8 illustrates an example sensing apparatus, according to some embodiments.

FIG. 9 illustrates an example electronic device for sensing, according to some embodiments.

FIGS. 10A-10B are simplified diagrams illustrating example signals generated by sensing technology, according to some embodiments.

FIG. 11 is a simplified diagram illustrating an example sensing apparatus, according to some embodiments.

FIG. 12 illustrates an example sensing apparatus, according to some embodiments.

FIG. 13 illustrates an example electronic device for sensing, according to some embodiments.

FIG. 14 illustrates example geometries of a tactile finger, according to some embodiments.

FIGS. 15A-15C illustrate example devices for tactile finger sensors, according to some embodiments.

FIG. 16 is a simplified diagram illustrating an example method for manufacturing a tactile sensor, according to some embodiments.

FIGS. 17A-17F illustrate example tactile finger sensors, according to some embodiments.

FIG. 18 is a simplified diagram illustrating an example electronics setup for tactile finger sensors, according to some embodiments.

FIG. 19 is a simplified diagram illustrating example configurations for sampling PVDF, according to some embodiments.

FIGS. 20A-20C illustrate example probing setups for evaluating tactile finger sensors, according to some embodiments.

FIG. 21 illustrates an example sensing method, according to an embodiment.

FIG. 22 illustrates an example method for manufacturing a sensing device, according to an embodiment.

### DETAILED DESCRIPTION

Embodiments disclosed herein are related to tactile sensing techniques. Haptic technology, or kinaesthetic communication, utilizes vibrations, forces, and motions to create a sense of touch. With development in haptic technology, physical sensory perception of human skin can be mimicked and harnessed for technological advances in fields like robotics, medical, consumer products, security systems, automotive, etc.

Human skin contains mechanoreceptors for both static and dynamic sensing. Static sensing is the detection of slowly-changing stimuli, like constant forces, while dynamic sensing is the detection of fast-changing stimuli, like vibrations and the onset of touch. Dynamic sensing plays an important role in detecting the making/breaking of contact, sensing slip, sensing surface texture, and receiving tactile feedback via a held object (e.g., tool use).

A transducer is a device that converts one form of energy into another, such as converting mechanical energy into electrical signals. Transducers used for dynamic sensing have a high frequency response and sensitivity, and often respond only to changes in signals, not static forces. For example, a piezoelectric effect is the ability of certain materials to generate an electric charge in response to applied mechanical stress. This piezoelectric effect responds to the mechanical stress instantaneously and continuously, meaning the material generates a charge as soon as the stress is applied and continues to do so as long as the stress is present. When mechanical stress is applied to a piezoelectric material, it causes a deformation in the physical structure of the material. This deformation leads to a redistribution of electrical charges within the material, resulting in an electric charge on the surface of the material. The piezoelectric material continuously responds to changes in mechanical stress. When the stress varies over time, the generated electric charge will also vary accordingly. The dynamic sensing transducers would capture real-time changes on the mechanical stress being applied and respond to these changes dynamically. For instance, a piezoelectric accelerometer detects changes in acceleration by measuring the mechanical stress applied to the piezoelectric material. As the acceleration changes, the mechanical stress on the piezoelectric material changes, generating a corresponding electric charge. The generated electric charge is converted into an electrical signal that represents the acceleration.

There remains a significant gap in exploring the complementary nature between static and dynamic sensing techniques. Static sensing measures physical quantities that are constant or change very slowly over time. For instance, static sensing can be based on resistive, capacitive, or inductive principles where the sensor's output is based on the physical quantity. Combining dynamic and static sensing at the same time is challenging due to the differing requirements for response time, sensitivity, stability, and signal processing, etc. For example, there is a lack of tactile fingers that integrate force sensing with distributed vibration sensing in the hundreds of Hz. Furthermore, research on leveraging multimodal tactile feedback to enhance manipulation skills is relatively scarce. In robotics, there are many ways to implement dynamic sensing, including accelerometers, microphones, hydrophones, piezoelectrics, and piezoresistors. Building tactile fingers with distributed vibration sensing across a complex finger-shaped surface remains a challenge. Polydimethylsiloxane (PDMS), also known as dimethylpolysiloxane or dimethicone, is a silicone polymer with a wide variety of uses including sensing applications, medical phantoms, and organ-on-chip studies, etc.

Tactile sensing technology can utilize a range of physical effects. For example, a piezoelectric transducer monitors the piezoelectric effect of an electric charge in response to applied mechanical stress. For a certain material, its property can cause charges to be generated when the material is under stress. Piezoelectric sensors measure the charge produced when the sensor is stimulated. Piezoelectricity can also be utilized for actuators.

In an embodiment, a bimodal finger is disclosed that combines distributed force and vibration sensing, as a platform for studying multimodal tactile sensing and how it can benefit manipulation. A piezoelectric polyvinylidene fluoride (PVDF) is used for vibration modality with custom electrode patterns. Capacitive sensors can be used as force modality to implement force sensing. In some embodiments, a sensor system contains custom-fabricated, taxelized PVDF films for achieving high-resolution taxelization and compact integration. In other embodiments, a sensor system contains other devices like PVDF strips as a more accessible solution (e.g., does not require cleanroom fabrication tools). Aspects of the disclosed techniques combine a distributed, high frequency (hundreds of Hz) vibration sensing transducer type with a static force sensing transducer type in a tactile finger. Compared to unimodal sensors that measure vibrations and static pressures, multi-modality provides the advantage that each modality's sensitivity can be tuned to target different stimuli. In some embodiments, PVDF and capacitive transducers are integrated together into a single tactile finger. In other embodiments, a single taxelized PVDF sheet is used with multiple independent taxels (sometimes also referred to as tactile elements) in a tactile finger with a curved finger surface.

In some embodiments, a tactile finger functions with distributed vibration sensing using PVDF. PVDF films can be custom fabricated with individualized taxels (sometimes also referred to as electrodes). PVDF responds to changes in input, and is sensitive to very light touches and vibrations (the response is “spiky”).

In some embodiments, PVDF films can be combined with capacitive sensing as an underlying static force modality. These modalities are complementary, with PVDF targeting vibrations and capacitive sensors measuring constant pressures.

In some embodiments, a tactile finger can include custom-made, taxelized PVDF film. The sensor interfaces with electronics with a heat seal connector. The electronics can include a printed circuit board (PCB), a microcontroller development system, amplifiers, heat seal connection, ports for capacitive sensors, etc.

In some embodiments, a tactile finger prototype can include PVDF strips with the electronics. In some embodiments, sensing techniques include a system that combines PVDF with capacitive sensors into one bimodal finger. Outputs of capacitive sensors are sampled with data sampling and/or conversion devices.

In some embodiments, the combined modalities are complementary. For example, PVDF targets detecting initial touch and vibrations, while capacitive sensors target static pressures. By combining these modalities, more complex manipulation tasks can be accomplished with the disclosed sensing techniques.

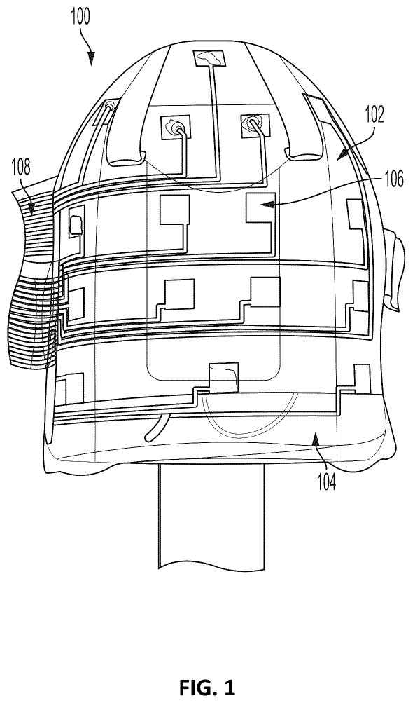

FIG. 1 shows a tactile finger prototype according to an embodiment. Specifically, FIG. 1 shows an example sensing apparatus 100 including a sensing device 102 and a supporting structure 104. The sensing device 102 further includes at least one sensing unit 106 and a data interconnect 108 for the at least one sensing unit 106. The data interconnect 108 includes at least one data trace that inputs data (for instance, instructions and configuration parameters controlling the operation of the sensing device 102) to and/or outputs data (for instance, data representing sensed signals corresponding to the physical effect that is being sensed by the sensing device 102) from the at least one sensing unit 106. The data interconnect 108 connects the sensing device 102 to a data and signal processing device that can include a printed circuit board (PCB), a microcontroller development system, amplifiers, heat seal connection, ports for capacitive sensors, etc.

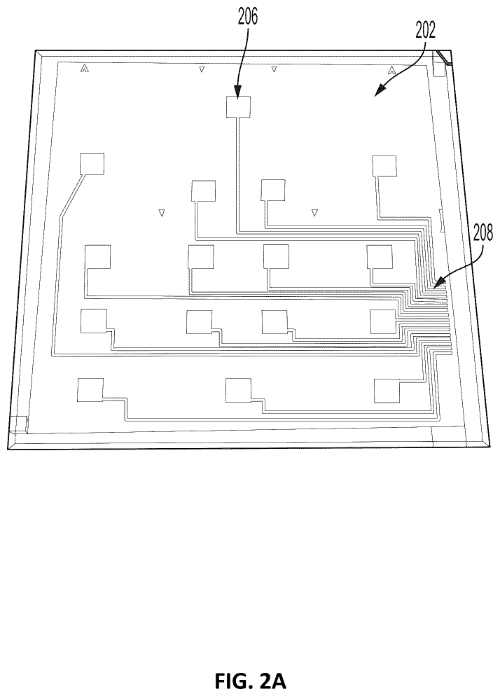

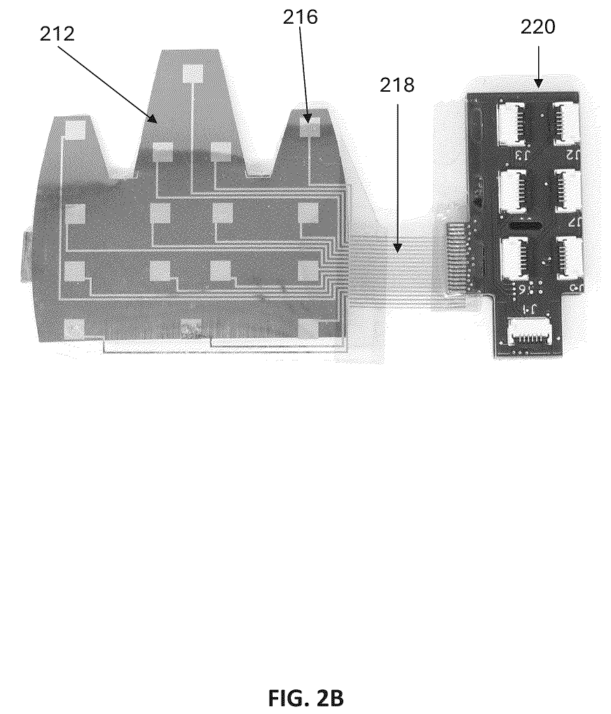

FIG. 2A shows a custom-made, taxelized PVDF film for a tactile finger sensor, according to an embodiment. Specifically, FIG. 2A shows another example sensing device 202 including at least one sensing unit 206 and a data interconnect 208 for the at least one sensing unit 206. The data interconnect 208 includes at least one data trace that inputs data (for instance, instructions and configuration parameters controlling the operation of the sensing device 202) to and/or outputs data (for instance, data representing sensed signals corresponding to the physical effect that is being sensed by the sensing device 202) from the at least one sensing unit 206. The data interconnect 208 connects the sensing device 202 to a data and signal processing device that can include a printed circuit board (PCB), a microcontroller development system, amplifiers, heat seal connection, ports for capacitive sensors, etc.

FIG. 2B shows another example sensing device 212 including at least one sensing unit 216, a data interconnect 218, and a signal processing device 220, according to an embodiment. The signal processing device 220 receives data representing sensed signals corresponding to the physical effect that is being sensed by the sensing device 212, and processes the data to extract information and/or for further processing. In some examples, the electronics of the signal processing device 220 can include a heat seal connector.

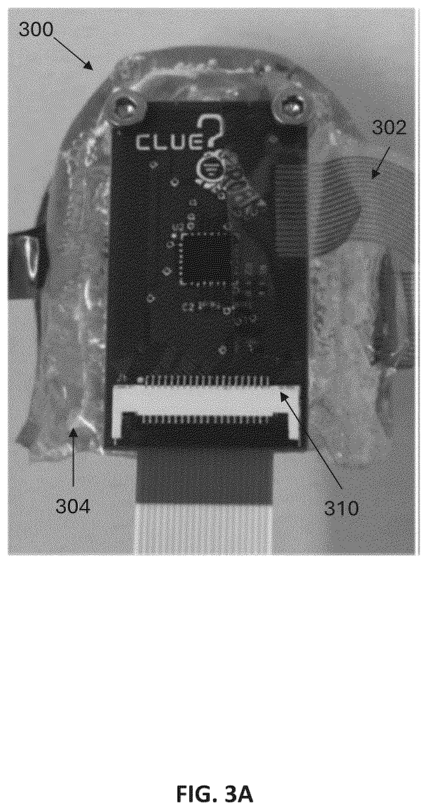

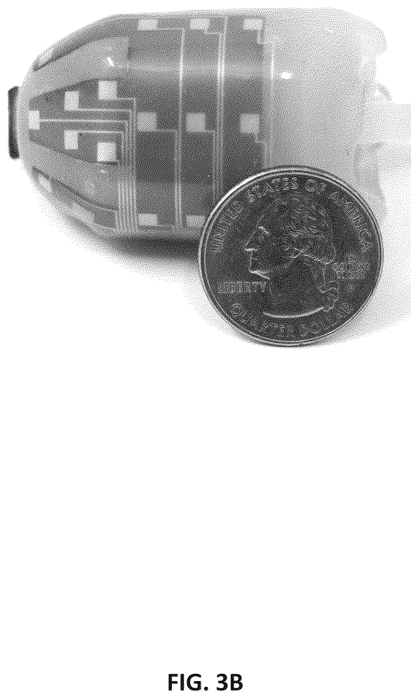

FIG. 3A shows sensor interfaces with custom electronics for a tactile finger sensor, according to an embodiment. In the example shown by FIG. 3A, an example sensing apparatus 300 includes a sensing device 302, a supporting structure 304, and a signal processing device 310 connected to the sensing device 302. The signal processing device 310 receives data representing sensed signals corresponding to the physical effect that is being sensed by the sensing device 302, and processes the data to extract information and/or for further processing. In some examples, the electronics of the signal processing device 310 can include a heat seal connector. FIG. 3B shows another example sensing apparatus from another perspective of view, according to an embodiment.

FIG. 4 illustrates an example circuitry for sensor interfaces with custom electronics for the signal processing device 310, according to an embodiment. In some examples, the circuitry can include a heat seal connection.

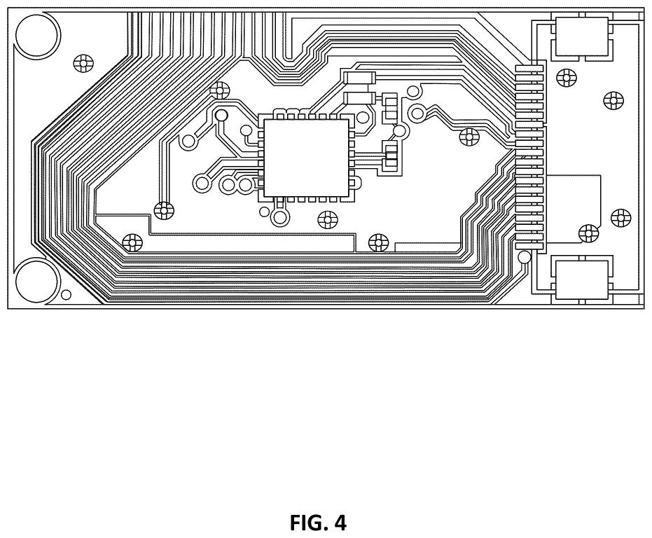

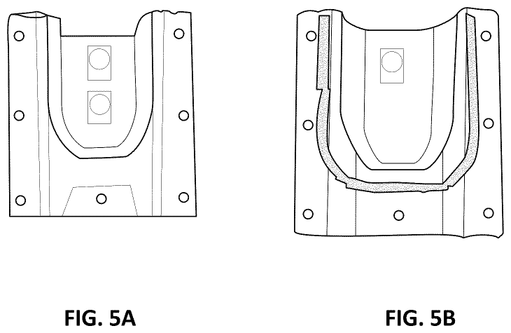

FIGS. 5A-5B show a front side and a back side of resin molds for fabrication of a tactile finger sensor including the supporting structure, according to an embodiment. In some examples, the resin is encased by an elastomer polydimethylsiloxane (PDMS) material. An elastomer material is a rubbery material composed of long chainlike molecules, or polymers, that are capable of recovering their original shape after being stretched to great extents. The elastomer creates a compliant surface that distributes applied strain. The sensor can contain a stiffer outer layer of PDMS to provide a durable coating.

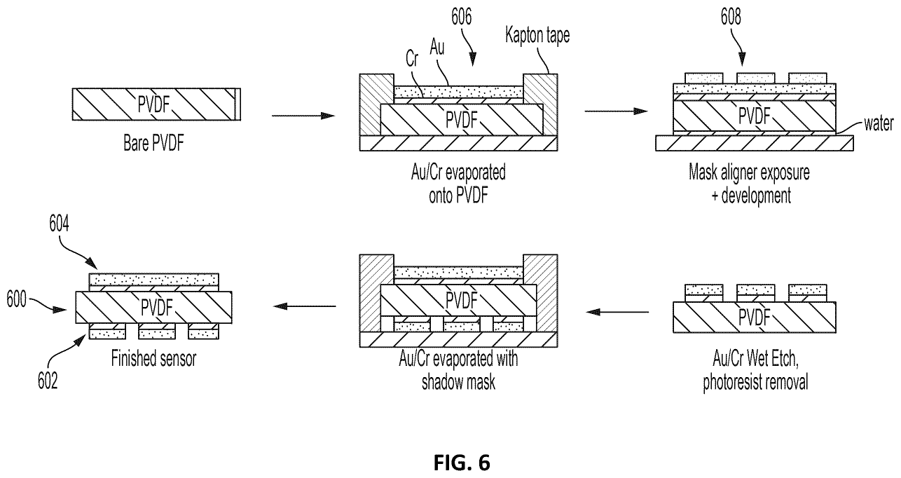

Referring to FIG. 6, in some embodiments, the process flow for fabrication of a sensing device 600, for instance, a taxelized PVDF films includes fabricating an array of electrodes 602 with corresponding traces and a back plane 604 to complete each capacitor. For example, the array can contain around 16 electrodes and traces that run to the edge of the sensor for connection to external electronics. In an embodiment, a metal stack 606 on each side can have around 20 nm of a chrome adhesion layer and around 150 nm of gold, which is evaporated via electron beam onto, for example, 4.5 cm×4.5 cm pieces of 100-micron thick PVDF. The array of electrodes 602 and traces are photolithographically patterned using a photomask 608 to pattern photoresist and wet etching to transfer the pattern to the metal stack 606. A back plane 604 is patterned using shadow mask deposition. Once fully patterned, excess PVDF is cut off with a precision knife to create the final geometry. The sensor device 600 is then connected to heat seal connectors via hot bar bonding to the sensor traces for future connection to off-sensor PCBs. In an embodiment, the electrodes can also be configured to provide integral shielding. For example, a larger outside electrode can be grounded, providing a shielding functionality for the patterned electrodes on the interior. A differential or paired structure can also be considered using two layers of the sensing medium, with appropriate amplifiers for reduction of system noise. In another embodiment, the sensor layer, for example, the array of electrodes 602 and traces are fabricated between two layers of a compliant material.

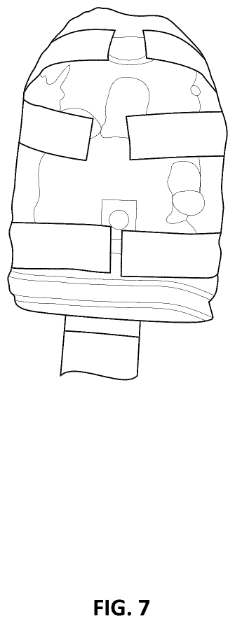

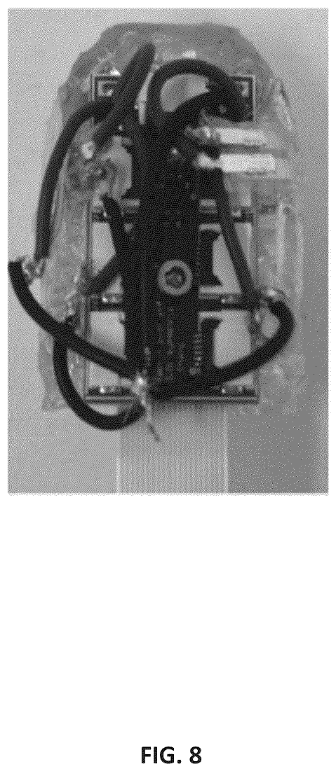

FIG. 7 shows a tactile finger prototype with non-custom PVDF strips, according to an embodiment. FIG. 8 shows electronic wirings for a tactile finger sensor, according to an embodiment.

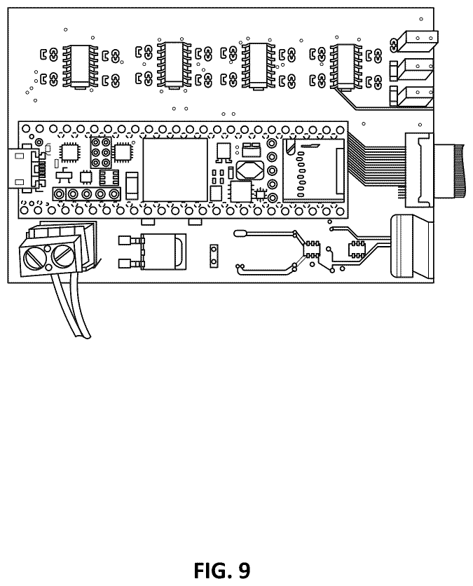

FIG. 9 illustrates an example circuitry of the signal processing device 310 for processing signals from a tactile finger sensor, according to an embodiment. In some examples, the circuitry can include a microcontroller and amplifiers. The circuitry is implemented on an off-sensor PCB and can work with both a tactile finger with custom-made PVDF film and a tactile finger with non-custom PVDF strips.

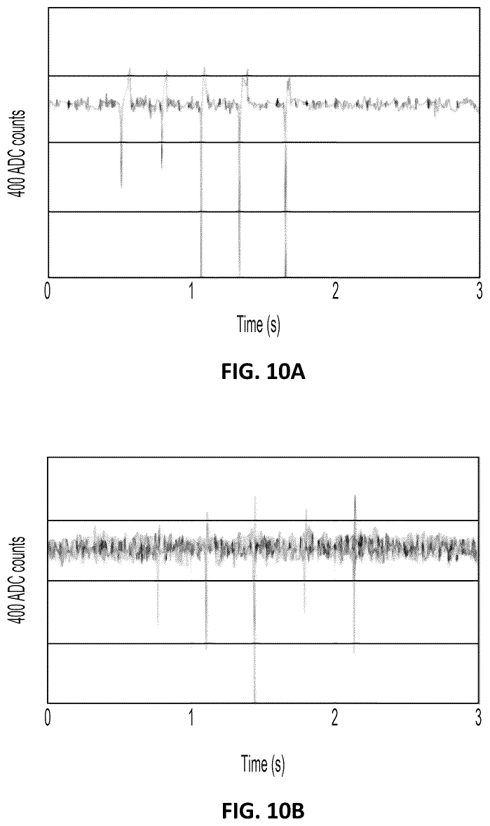

FIGS. 10A and 10B illustrate signal samples from tactile finger sensors, for instance the sensing device 102 in response to light taps visualized at 200 Hz. In some examples, the plotted signal shows multiple transducers being stimulated from a single tap.

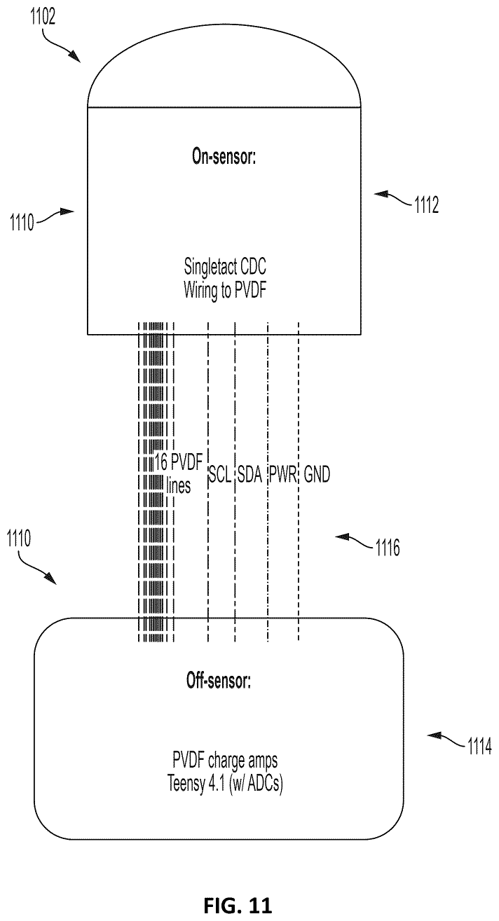

FIG. 11 illustrates an electronics setup for tactile finger sensors, according to an embodiment. In the example shown in FIG. 11, a sensing device 1102 connects to a signal processing device 1110 via an interconnect. The signal processing device 1110 receives data representing sensed signals corresponding to the physical effect that is being sensed by the sensing device 1102, and processes the data to extract information and/or for further processing. The signal processing device 1110 further includes an on-sensor circuit 1112 and an off-sensor circuit 1114, the on-sensor circuit 1112 and the off-sensor circuit 1114 linked with a signal processing link 1116. The signal processing link 1116 includes a plurality of data lines that input data (for instance, instructions and configuration parameters controlling the operation of the sensing device 1102) to and/or output data (for instance, data representing sensed signals corresponding to the physical effect that is being sensed by the sensing device 1102) from the on-sensor circuit 1112 and the sensing device 1102. In some examples, the electronics of the signal processing device 1110 can include a heat seal connector.

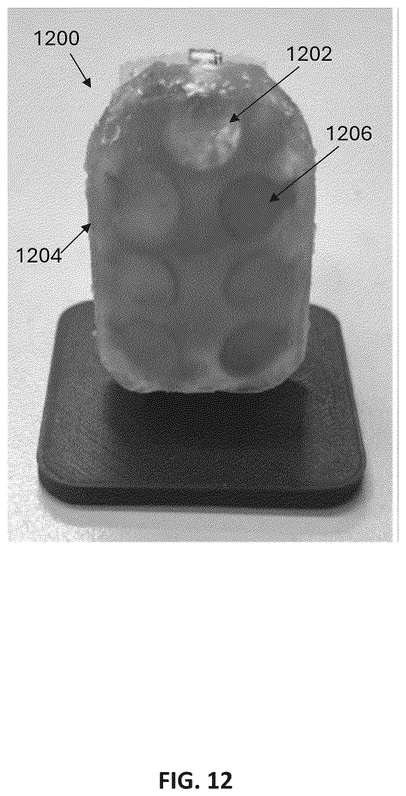

FIG. 12 illustrates a tactile finger sensor with capacitive sensors, according to an embodiment. Specifically, FIG. 12 shows an example sensing apparatus 1200 including a sensing device 1202 and a supporting structure 1204. The sensing device 1202 further includes at least one sensing unit 1206 that operates at a different mode than the sensing device 102 and the sensing unit 106 (shown above as described in FIG. 1). In an embodiment, the sensing device 1202 performs static sensing that measures a physical quantity that is constant or changes very slowly over time. For instance, static sensing can be based on resistive, capacitive, or inductive principles where the sensor's output is based on, respectively, the physical quantity of resistance, capacitance, or inductance. Such different sensing operation has different response time, sensitivity, stability, and signal processing, etc. The sensing device 1202 can connect to a data interconnect that inputs data (for instance, instructions and configuration parameters controlling the operation of the sensing device 1202) to and/or outputs data (for instance, data representing sensed signals corresponding to the physical effect that is being sensed by the sensing device 1202). The data interconnect connects the sensing device 1102 to a data and signal processing device that can include a printed circuit board (PCB), a microcontroller development system, amplifiers, heat seal connection, ports for capacitive sensors, etc.

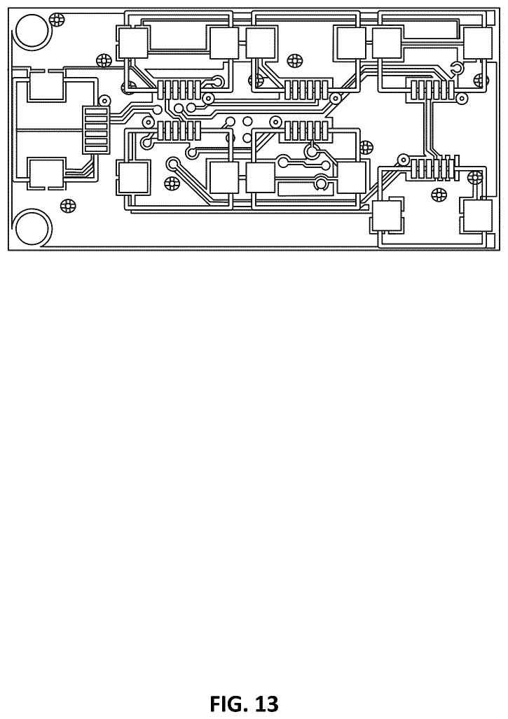

FIG. 13 illustrates an example circuitry for sensor interfaces with custom electronics for the signal processing device 310 connecting to the sensing device 1202, according to an embodiment. In some examples, the circuitry includes ports for connection with capacitive sensors.

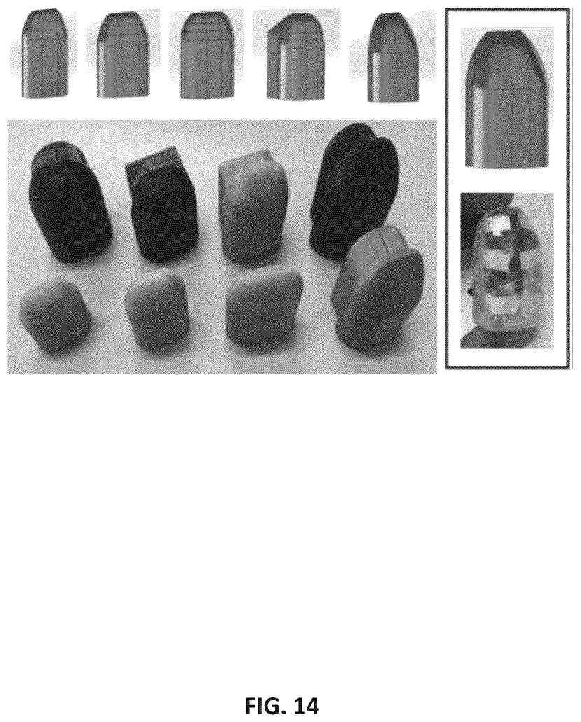

Referring to FIG. 14, in some embodiments, the finger is curved and sensorized everywhere except the back—all areas where contacts are likely. In an embodiment, there are no protrusions (.e.g., convex areas) that are unsensorized. In other embodiments, there are flat patches on the front to increase contact stability. For example, the finger comes to a tip to enable picking up small objects off of a flat surface with a pinch grasp. The overall size can be similar to a human thumb, but can be limited by the size of the PCBs and the capacitive sensors, which can have a diameter of around 8 mm. The molds can be modified to adjust the geometry in further embodiments.

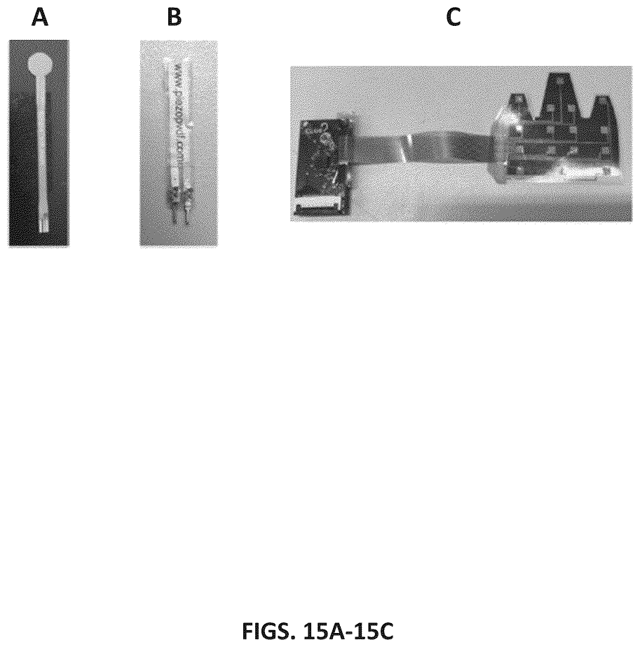

FIG. 15A shows exemplary capacitive sensors that are single-point capacitive force sensors with good SNR and limited hysteresis. They are an accessible way to integrate force sensing into a finger. With custom capacitive arrays (which is a plausible option), in some cases, it could be hard to achieve performance as good as the single-point capacitive force sensors. An aspect of these capacitive sensors is that they are around 8 mm in diameter (fairly large), and each signal has its own tail, which is to be routed to a PCB.

In other embodiments, as illustrated by FIG. 15B, PVDF strips can be cut to a desired size. The PVDF strips are a sheet of PVDF with an electrode deposited on each side. They have two leads crimped to them, one being connected to measure a generated current (or send current, if using them as an actuator).

In further embodiments, as illustrated by FIG. 15C, custom-made PVDF created in clean rooms provide continuous films of PVDF that are deposited with electrodes and traces in customizable patterns. The traces on the film can be connected to via a heat seal connector-a flexible connector that can be adhered by applying heat and pressure. In some examples, these connectors contain an anisotopic, conductive adhesive in the traces. When heated, the traces bond and connect to a sensor (or other interface). Because the adhesive is anisotropic, the connection is only in the direction of the traces (i.e., they don't short).

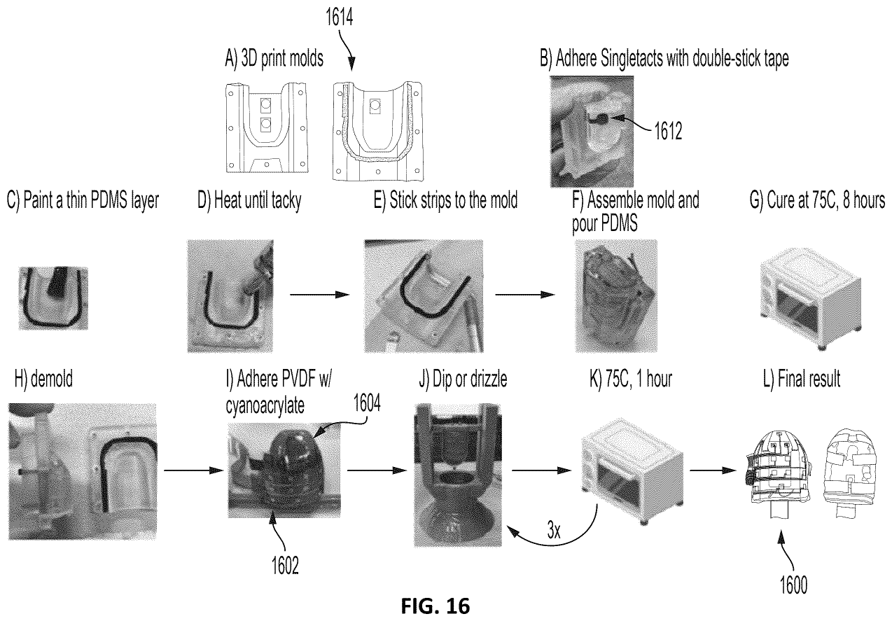

FIG. 16 illustrates, in some embodiments, a sensing apparatus 1600 (for instance, a sensor finger) including a first sensing device 1602 and a second sensing device 1612, and method of fabricating the sensing apparatus 1600. 3D-printed molds 1614 can be used to cast a layer of PDMS onto a supporting structure 1604 (for instance, a 3D-printed rigid skeleton). The second sensing device 1612 including, for example, capacitive sensors, is attached to the supporting structure 1604. Then, a stiffer outer layer of PDMS is applied using a dipping process. This two-step process allows embedding the first sensing device (for instance, a PVDF sensor) between the two layers. A double-sided tape can be used to stick the capacitive sensors to the skeleton, and route the tails through the skeleton. In one example, the tails stick out the back of the skeleton during molding. Then, the molds are sprayed with a release agent (e.g., Mann Ease Release 200) to reduce adhesion between the mold and PDMS.

In an embodiment, to apply non-custom PVDF, a thin layer of PDMS is applied to the mold and is partially cured with a heat gun until it is tacky. Then, the strips are stuck to the mold in a desired configuration. Mixed and degassed PDMS is poured (e.g., 30:1 base to curing agent weight ratio) into the prepared mold and it is cured in an oven at 75 C for around 8 hours. After demolding, excess PDMS is removed from the back of the finger with a precision knife. When using custom PVDF, the sensor may be adhered to the finger with cyanoacrylate after casting the finger.

In another embodiment, the finger is dipped in stiffer PDMS (e.g., 10:1 ratio) to apply a thin outer coating on a top of the sensor, and it is cured at 75 C for around one hour (the dip process can be similar to making a candle). This procedure is completed, for example, three times to form a coating of around 1 mm. In other embodiments, instead of a dip, a gradual drizzle can be applied over the finger which lets the PDMS drip down the sides (similar to drip candy coating). This process can waste less PDMS and provide an even layer.

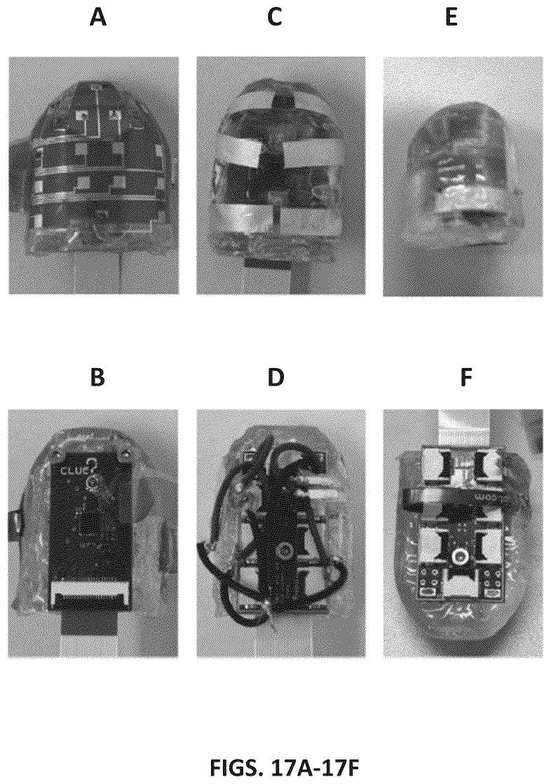

Referring to FIGS. 17A-17F, in some embodiments, sensors are connected to electronics with wiring for the PVDF. FIGS. 17A-17B illustrate a tactile finger with a custom-made, taxelized PVDF film and associated electronics, according to an embodiment.

FIGS. 17C-17D illustrate a tactile finger with non-custom PVDF strips and associated electronics, according to an embodiment. When suspending the non-custom PVDF strips, as an example, around 6 strips can be positioned in a finger so they are suspended in the middle of the elastomer and in repeatable locations. The sensors themselves can be thin and flimsy, so they move easily after positioning them. In some examples, the leads coming off the PVDF are fairly long and take up too much space to sit in the elastomer. Instead, they dangle out the back of the finger. The wires soldered to the PVDF can be removed prior to placing in the mold. Otherwise, movement of the heavy wires can move the placement of the strip. The leads can go around the skeleton, not through it. In some embodiments, the leads are not very flexible, so they cannot be fed through a tight space without affecting the strip placement. Strips are placed within the mold before the mold is assembled. Otherwise, it can be challenging to position them. The strips and their leads should not be disturbed when assembling the mold, so there should be enough tolerance to assemble the mold without disturbing the leads. In other examples, the strips are positioned on a pre-cured finger, rather than inside the mold. However, this could be messy without a good adhesive to secure the strips in place. In further examples, a spray-on adhesive can be used that dries quickly (e.g., spray-on double-stick tape), making a “stencil” that can fit over a pre-cured finger. Then, the spray-on adhesive is used to secure the strips with the stencil before drizzling the outer PDMS coating.

In an embodiment, the suspended PVDF in a compliant structure has several advantages. For instance, the outside compliant layer to the PVDF material protects the device from scratching or other external insult, the compliance of the stack allows for sensor elements to be more useful as grippers or actuation elements, and the elastomer on the inside allows for the improved compliance upon contact to strain the PVDF and provide a useful signal.

FIGS. 17E-17F illustrate a tactile finger with capacitive sensors, according to an embodiment.

In some embodiments, when suspending custom PVDF films, the single film is stiffer than the strips, such that using PDMS as an adhesive may not be suitable. Cyanoacrylate works as an adhesive to bond the film either to a pre-cured finger or to the inside of the mold. However, it can take longer to dry and provide a good bond. In other embodiments, double stick tape can fit even better for this, since there's no drying time. However, double stick tape can be difficult to handle and reposition. Using the spray-on adhesive mentioned above is a suitable way to stick the sample inside the mold.

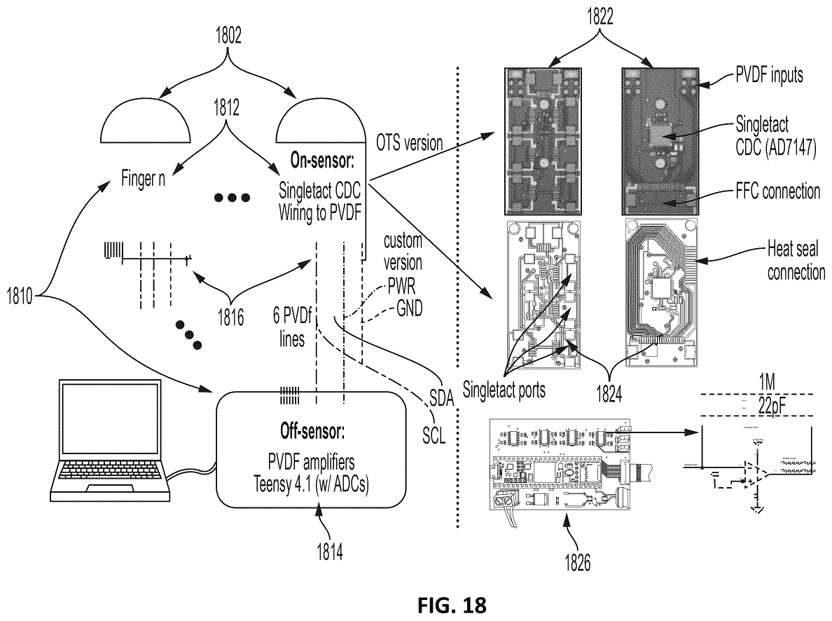

Referring to FIG. 18, in some embodiments, the overall layout of electronics includes, for example, two printed circuit boards (PCBs): an “on-sensor” board and “off-sensor” board. The on-sensor board fastens to the back of the finger bone and connects to the sensors. The off-sensor board sits elsewhere and connects to one or multiple fingers via a cable, e.g., Flat-Flexible Cables (“FFC”). The off-sensor board contains a microcontroller and communicates with a PC computer using micro-ROS.

In the example shown in FIG. 18, at least one sensing device 1802 (which can be an array of sensing devices according to an embodiment) connects to a signal processing device 1810 via an interconnect. The signal processing device 1810 receives data representing sensed signals corresponding to the physical effect that is being sensed by the at least one sensing device 1802, and processes the data to extract information and/or for further processing. The signal processing device 1810 further includes an on-sensor circuit 1812 and an off-sensor circuit 1814, the on-sensor circuit 1812 and the off-sensor circuit 1814 linked with a signal processing link 1816. The signal processing link 1816 includes a plurality of data lines that input data (for instance, instructions and configuration parameters controlling the operation of the at least one sensing device 1802) to and/or output data (for instance, data representing sensed signals corresponding to the physical effect that is being sensed by the at least one sensing device 1802) from the on-sensor circuit 1812 and the sensing device 1802. In some examples, the electronics of the signal processing device 1810 can include a heat seal connector. In one embodiment, the on-sensor circuit 1812 of the signal processing device 1810 is implemented by a circuit board 1822 and/or a circuit board 1824. In another embodiment, the off-sensor circuit 1814 of the signal processing device 1810 is implemented by a circuit board 1826.

In some embodiments, with PVDF Electronics, the PVDF is connected to the on-sensor board using either heat seal connectors or wires. Analog signals are routed through the FFC to the off-sensor board. The off-sensor board contains current amplifiers with high-impedance operational amplifiers (op amps), followed by the microcontroller's Analog-to-digital Converters (ADCs) which digitize the signal. Current amplifiers (as opposed to voltage amplifiers) can be used because their output is independent of the cable capacitance—a relevant point since long cables are used. The sample frequency can be at, e.g., around 1000 Hz.

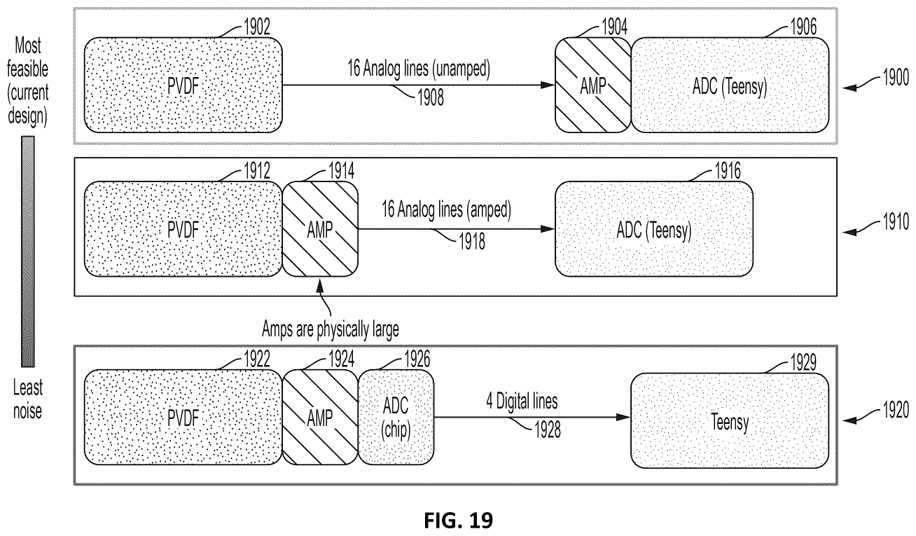

Referring to FIG. 19, in some embodiments, multiple components are placed on the on-sensor PCBs, where space is limited. PVDF signals can have extremely high impedance (i.e., weak). In practice, this means that the signal is susceptible to, e.g., accumulating noise or being loaded by the amplifier/ADC. As a result, it would be helpful for the signals to be amplified and digitized as close to the transducer as possible. Different combinations of layouts for how to read the PVDF can be configured. Tradeoffs among the various configurations include balancing the amount of electronics and the signal quality.

In some embodiments, capacitance measurements are prone to noise. It's helpful to have the signals digitized as close to the sensor as possible, and to provide proper shielding. As a result, a capacitance-to-digital converter (CDC) can be included on the on-sensor board, which communicates digitally with the microcontroller.

The capacitive sensors can include their own electronics board containing a CDC and an Inter-integrated circuit (I2C) interface. In some cases, this interface board can connect to only one sensor, so another CDC for capacitive tactile sensing (e.g., AD7147) can be used. The I2C interface is used to communicate with the microcontroller. Serial peripheral interface (SPI) can also be used, as I2C is slower and susceptible to increasing cable capacitance. The amplifier and ADC circuitry can be put on the PVDF itself for integration. SPI is also easier to buffer to reduce noise because the lines are unidirectional, and is generally simpler to deal with.

In further embodiments, for debugging, a spectrum analyzer and probe station can be used to run capacitance measurements on both the board and the interface board, and the capacitance changes are comparable between the two. Some reference capacitors can also be used.

In some embodiments, the working transducers are sensitive to light touches. Materials such as chromium and/or titanium can be used in the adhesion layer. Titanium, as an example, can be used instead of chromium to make the traces more ductile.

In an embodiment, a device with non-custom PVDF can be more sensitive and less noisy than a custom version. This is in part due to the size of the electrodes, which are proportional to the amount of charge generated. There can be a lot of noise introduced by the long wiring of the custom sample. To help improve signal quality, the following can be done: increase the size of the pads, amplify or digitize the signal on the on-sensor board, add some filtering circuitry, particularly to reduce the 60 Hz noise from the power supply, add ground traces between signal and digital traces on the cabling to reduce interference, and/or use shielded, twisted cables, and/or use different variants of PVDF (e.g., P(VDF-TrFE)) having higher piezoelectric constants and can therefore produce a stronger signal.

In some embodiments, the device with non-custom PVDF has higher sensitivity and is more reliable and robust (no lead time, connections are robust, etc.). However, the non-custom configuration is near the limit of taxel complexity and the limit of wiring options. In other embodiments, the device with custom PVDF has custom taxel arrangements and size, compact wiring, and many ways to improve the signal quality and sample robustness. However, it can have lower sensitivity, and involves a clean room therefore requiring longer lead times and can be less robust.

In the example shown in FIG. 19, in a sensing setup 1900 according to one embodiment, a sensing device 1902 is connected via an interconnect 1908 (for instance, 16 analog lines without amplification) with an amplifier circuit 1904 integrated with an analog-to-digital converter circuit 1906. In another sensing setup 1910 according to another embodiment, a sensing device 1912 is integrated with an amplifier circuit 1914, which is connected via an interconnect 1918 (for instance, 16 analog lines with amplification) with an analog-to-digital converter circuit 1916. In yet another sensing setup 1920 according to another embodiment, a sensing device 1922 is integrated with an amplifier circuit 1924 and an analog-to-digital converter circuit 1926, which is connected via an interconnect 1928 (for instance, 4 digital data lines) with a microcontroller 1929. In an embodiment, electrodes on the sensing devices can also be configured to provide integral shielding. For example, a larger outside electrode can be grounded, providing a shielding functionality for the patterned electrodes on the interior. A differential or paired structure can also be considered using two layers of the sensing medium, with appropriate amplifiers for reduction of system noise.

The disclosed sensing techniques can be combined with object recognition for providing vibration feedback, with a “feeling” action to learn about the texture of an environment. Vibration feedback can also allow exploration in a much more unstable environment (e.g., a robot can react quickly to light touches, so not as much force is needed for a contact). Having two modalities means they can always provide cross-reference information (e.g., a set of labels with which the sensed data can be annotated to classify the data's elements and/or properties) for each other because every response in one modality can correspond to an associated response in the other modality. For example, signals in one modality become labeled data for signals in the other modality due to the correlation between them. It is advantageous to have this self-supervision to recognize signal anomalies (meaning that signal should not be trusted), e.g. a change in noise levels, noise spikes, sensor drift, etc. Vibration signals can be used to estimate static forces. Inherently vibration signals do not contain information about low frequencies (it's essentially a high pass filtered response), but vibrations can be analyzed to estimate for force magnitudes. Meissner corpuscles (human RA-I receptors) have a greater response in a particular direction, which has information about shear forces. PVDF has different piezoelectric constants in different directions as well. Some kind of unified representation combining vibration and static signals can help with manipulation tasks. If one modality starts to drift (and, an associated model starts degrading), self-supervision can be used to retrain a tactile model. As an example, vibration feedback is particularly important for tool use.

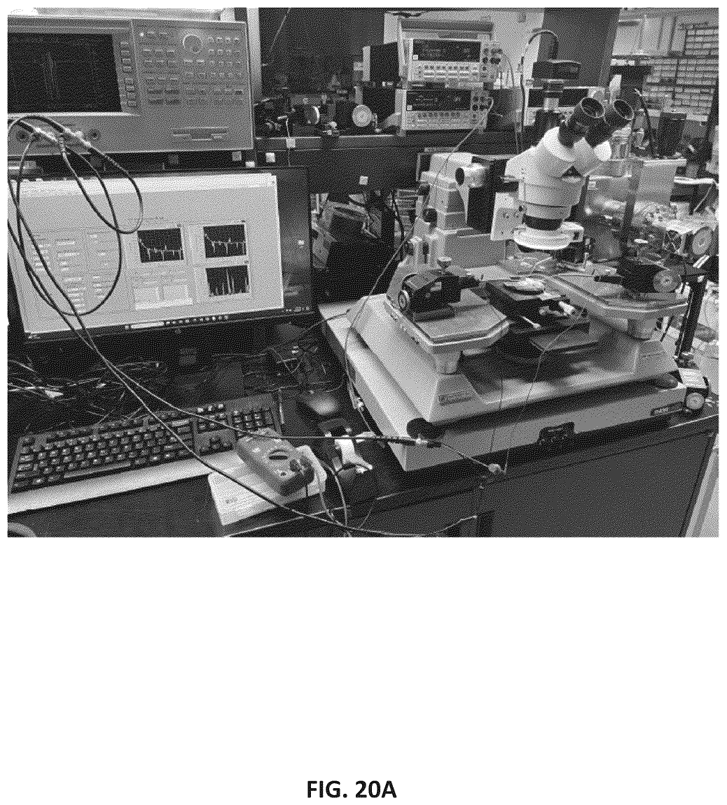

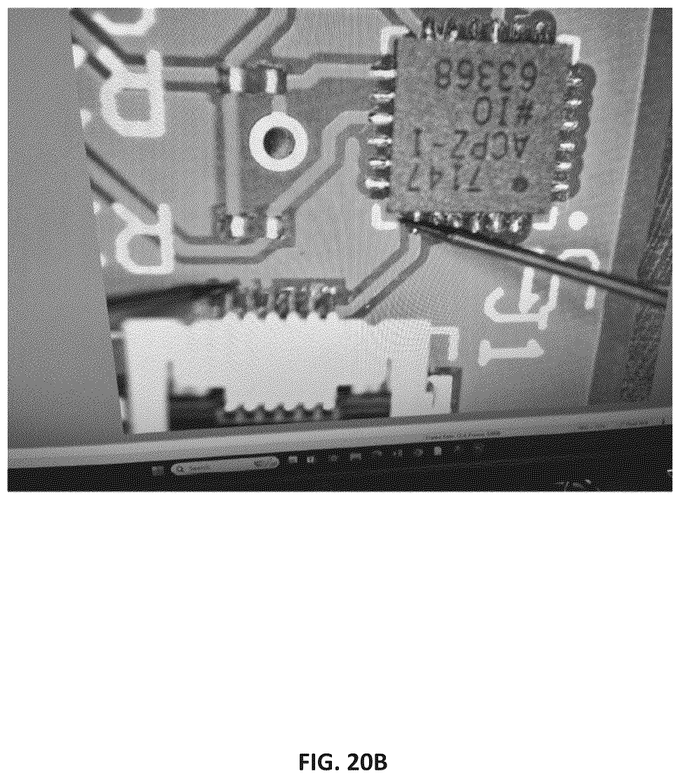

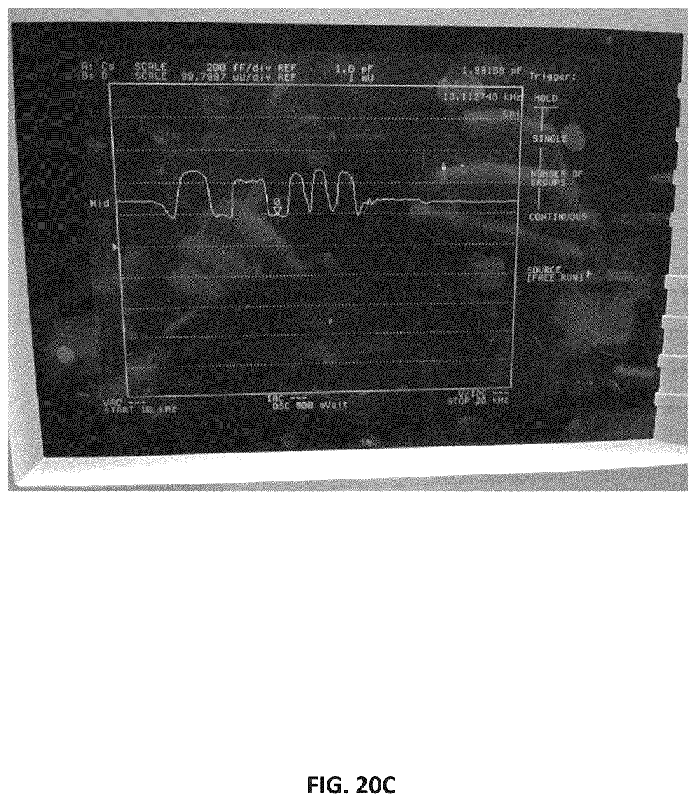

FIG. 20A illustrates a probing setup for measuring performance of tactile finger sensors, according to an embodiment. FIG. 20B illustrates a probe of the probing setup, according to an embodiment. FIG. 20C illustrates capacitance measurement results using the probing setup, according to an embodiment.

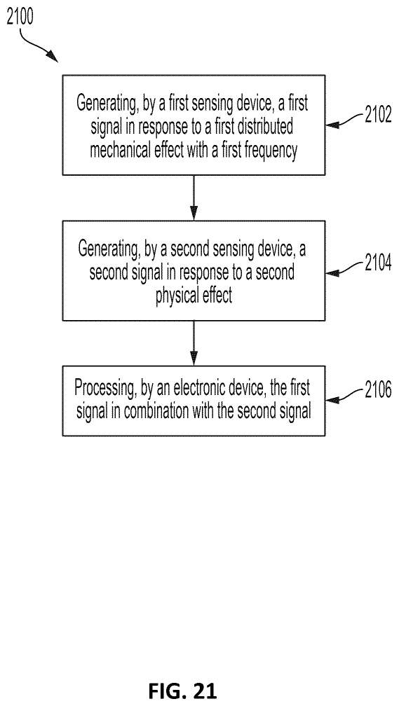

FIG. 21 illustrates an example method 2100 for tactile sensing, according to an embodiment. The method 2100 includes, at step 2102, generating a first signal in response to a first distributed mechanical effect with a first frequency by a first sensing device. The first sensing device monitors the first distributed mechanical effect with a first frequency corresponds to a change of a mechanical force. The method 2100 further includes, at step 2104, generating a second signal in response to a second physical effect by a second sensing device. The second sensing device can monitor a static physical effect which can be constant or change at a slower speed and lower frequency compared to the first distributed mechanical effect. Dynamic sensing with a higher frequency often responds to changes in signals, rather than static forces, with higher sensitivity. On the other hand, static sensing with lower frequency measures a physical quantity that is constant or changes very slowly over time. For instance, static sensing can be based on resistive, capacitive, or inductive principles where the sensor's output is based on, respectively, the physical quantity of resistance, capacitance, or inductance. Combining dynamic and static sensing at the same time includes processing two different sensed signals with differing requirements for response time, sensitivity, stability, and signal processing, etc. At step 2106, the method 2100 further includes processing, by an electronic device, the first signal in combination with the second signal.

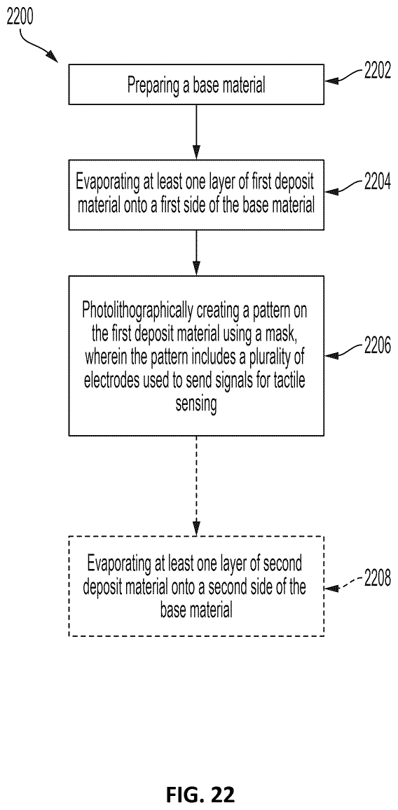

FIG. 22 illustrates an example method 2200 for manufacturing a tactile sensing device, according to an embodiment. The method 2200 includes, at step 2202, preparing a base material (for instance, a layer of PVDF). Further, the method 2200 includes evaporating at least one layer of first deposit material onto a first side of the base material, at step 2204. For instance, the first deposit material can be a metal stack consisting of one or more types of metal evaporated via electron beam. At step 2206, the method 2200 further includes photolithographically creating a pattern on the first deposit material using a mask, wherein the pattern includes a plurality of electrodes used to send signals for tactile sensing. For instance, the plurality of electrodes are formed as an array including corresponding traces and a back plane to complete as capacitive structure. The photolithography process includes using a patterned photomask to pattern photoresist and wet etching to transfer the pattern to the metal stack. In another embodiment, a back plane is patterned using shadow mask deposition onto the other side of the base material. At step 2208, the method 2200 can further include evaporating at least one layer of second deposit material onto a second side of the base material. Once fully patterned, excess PVDF is cut off with a precision knife to create the final geometry. In another embodiment, the method 2200 further includes depositing a first layer of a compliant material onto the base material, photolithographically creating a pattern on the first deposit material using a mask, wherein the first deposit material is on the first layer of the compliant material, and depositing a second layer of the compliant material onto the first deposit material. The layer on which sensors are patterned is fabricated between two layers of the compliant material.

As will be apparent to one of ordinary skill in the art from a reading of this disclosure, the present disclosure can be embodied in forms other than those specifically disclosed above. The particular embodiments described above are, therefore, to be considered as illustrative and not restrictive. Those skilled in the art will recognize, or be able to ascertain, using no more than routine experimentation, numerous equivalents to the specific embodiments described herein. The scope of the invention is as set forth in the appended claims and equivalents thereof, rather than being limited to the examples contained in the foregoing description.

1. A sensing apparatus, comprising:
a first sensing device;
a structure configured to support the first sensing device; and
an electronic device configured to process a first signal generated by the first sensing device,
wherein the first sensing device is configured to generate the first signal in response to a first distributed mechanical effect with a first frequency.

2. The sensing apparatus of claim 1, further comprising:
a second sensing device supported by the structure, the second sensing device configured to generate a second signal in response to a second physical effect,
wherein the electronic device is configured to process the first signal and the second signal.

3. The sensing apparatus of claim 2, wherein the first distributed mechanical effect with a first frequency corresponds to a change of a mechanical force.

4. The sensing apparatus of claim 2, wherein the second physical effect is a static effect with a second frequency lower than the first frequency.

5. The sensing apparatus of claim 2, wherein the first sensing device includes a polyvinylidene fluoride (PVDF) film.

6. The sensing apparatus of claim 5, wherein the PVDF film includes a plurality of tactile elements.

7. The sensing apparatus of claim 2, wherein the second sensing device includes a capacitive transducer.

8. The sensing apparatus of claim 2, wherein the second sensing device has a response time that is different than the first sensing device.

9. The sensing apparatus of claim 2, wherein the second sensing device has a sensitivity level that is different than the first sensing device.

10. A sensing method, comprising:
generating, by a first sensing device, a first signal in response to a first distributed mechanical effect with a first frequency;
generating, by a second sensing device, a second signal in response to a second physical effect; and
processing, by an electronic device, the first signal in combination with the second signal.

11. The sensing method of claim 10, wherein the first distributed mechanical effect with a first frequency corresponds to a change of a mechanical force.

12. The sensing method of claim 10, wherein the second physical effect is a static effect with a second frequency lower than the first frequency.

13. The sensing method of claim 10, wherein the first sensing device includes a polyvinylidene fluoride (PVDF) film.

14. The sensing method of claim 13, wherein the PVDF film includes a plurality of tactile elements.

15. The sensing method of claim 10, wherein the second sensing device includes a capacitive transducer.

16. The sensing method of claim 10, wherein the second sensing device has a response time that is different than the first sensing device.

17. The sensing method of claim 10, wherein the second sensing device has a sensitivity level that is different than the first sensing device.

18. A method for manufacturing a tactile sensing device, comprising:
preparing a base material;
evaporating at least one layer of first deposit material onto a first side of the base material; and
photolithographically creating a pattern on the first deposit material using a mask, wherein the pattern includes a plurality of electrodes used to send signals for tactile sensing.

19. (canceled).

20. The method of claim 18, wherein the base material is polyvinylidene fluoride (PVDF) film.

21. The method of claim 18, further comprising:
depositing a first layer of a compliant material onto the base material;
photolithographically creating a pattern on the first deposit material using a mask, wherein the first deposit material is on the first layer of the compliant material; and
depositing a second layer of the compliant material onto the first deposit material.
